(19) United States
(12) Patent Application Publication
(10) Pub. No.: US 2017/0059611 A1
(43) Pub. Date: Mar. 2, 2017

(54) COAXIAL INTEGRATED CIRCUIT TEST SOCKET

(71) Applicant: Oracle International Corporation, Redwood City, CA (US)

(72) Inventor: Ronald Lesnikoski, Santa Clara, CA (US)

(21) Appl. No.: 14/923,424

(22) Filed: Oct. 26, 2015

Related U.S. Application Data
(60) Provisional application No. 62/213,471, filed on Sep. 2, 2015.

(51) Int. Cl. G01R 1/04

(52) U.S. Cl. CPC G01R 1/0466

(57) ABSTRACT

Embodiments are described for integrating full-coaxial signal pins in an integrated circuit (IC) test socket. The socket can be made of a conductive metal (e.g., aluminum), and can be drilled with a large number of holes for conductive pins to interface between a printed circuit board (on which the socket is mounted) and an IC being tested. The pins can include ground pins, low-speed signal (and/or power) pins, and coaxial pin assemblies for high-speed signals (HSS). Each coaxial pin assembly can include a conductive HSS pin, having a HSS probe disposed in a spring-loaded HSS barrel, and an insulative bushing. The HSS pin is surrounded by the insulative bushing, which is disposed in a hole of the conductive socket body, thereby forming a full coaxial pin with controlled impedance characteristics.

### BACKGROUND

It is common for electrical systems, such as integrated circuits (ICs) to include various types of interconnects. For example, the interconnects can include input/output (I/O) pins, power and ground pins, and/or other electrical structures implemented on packages for integrated circuits, printed circuit boards, electrical sockets, electrical connectors, electrical interposers, and/or other types of electrical systems. In such structures, the conductors are often arranged in two-dimensional arrays in order to efficiently use the available area. As such, each interconnect is likely adjacent to multiple other interconnects.

Testing such interconnects often involves inserting the package (e.g., the IC package) into a test socket that electrically couples the various interconnect structures to a test environment. Interconnects in test sockets are often implemented as spring-compliant conductive pins integrated in a test socket body. As signal edge rates and frequencies continue to increase in many of the ICs being tested, test socket designers have increasingly had to contend with cross-talk, signal insertion and losses, signal integrity issues, etc. One common approach to addressing these issues has been to decrease the length of the contact pin in the test socket. Another traditional approach is to manufacture fully-encapsulated coaxial pin structures (e.g., two conductors separated by an insulator) to insert into a plastic test socket substrate. In this approach, the I/O signal return path in non-integrated, non-specific pin layouts tend to be very poor or nonexistent, and there is often little or no significant performance improvement in signal return losses or cross-talk that would justify the redesign of the test socket. Further, as the test socket pins get shorter, it can become increasingly difficult to ensure that all the package interconnects maintain reliable mechanical contact with their corresponding test socket interconnects (i.e., to maintain good electrical conductivity). For example, particularly in larger test socket structures, it can be difficult or impractical to make the parts flat enough to ensure package-to-socket contact over the entire interconnect array, which can drive use of very long spring probes with high compliance.

### BRIEF SUMMARY

Among other things, systems and methods are described for integrating full-coaxial signal pins in an integrated circuit (IC) test socket. The socket substrate can be made of a conductive metal (e.g., aluminum), and can be drilled with a large number of holes for conductive pins that interface between a printed circuit board (on which the socket is mounted) and an IC being tested. The pins can include ground pins, low-speed signal (and/or power) pins, and coaxial pin assemblies for high-speed signals (HSS). Each coaxial pin assembly can include a conductive HSS pin, having a HSS probe disposed in a spring-loaded HSS barrel, and an insulative bushing. The HSS pin is surrounded by the insulative bushing, which is disposed in a hole of the conductive socket body, thereby forming a full coaxial pin with controlled impedance characteristics.

According to one set of embodiments, an IC test socket is provided. The IC test socket includes: a conductive metal IC socket body comprising a plurality of holes; and a coaxial pin assembly installed in a first of the holes and comprising: a conductive high-speed signal (HSS) pin comprising a HSS probe disposed in a spring-loaded HSS barrel; and an insulative bushing disposed in the first hole and surrounding the HSS pin in such a way as to form a controlled spacing between an outer surface of the HSS pin and an inner surface of the first hole.

### BRIEF DESCRIPTION OF THE DRAWINGS

The present disclosure is described in conjunction with the appended figures:

FIG. 1 shows an illustrative integrated circuit (IC) test environment as a context for various embodiments;

FIGS. 2A and 2B show cross-sectional views of a portion of an illustrative integrated circuit (IC) test socket body having ground pins and power or low-speed signal (LSS) pins, respectively, according to various embodiments;

FIG. 3 shows cross-sectional views of a portion of an illustrative integrated circuit (IC) test socket body having coaxial pins for supporting high-speed signals (HSS), respectively, according to various embodiments; and

FIG. 4 shows a flow diagram of an illustrative method for providing a coaxial signal path in an integrated circuit (IC) test socket, according to various embodiments.

In the appended figures, similar components and/or features may have the same reference label. Further, various components of the same type may be distinguished by following the reference label by a second label that distinguishes among the similar components. If only the first reference label is used in the specification, the description is applicable to any one of the similar components having the same first reference label irrespective of the second reference label.

### DETAILED DESCRIPTION

In the following description, numerous specific details are set forth to provide a thorough understanding of the present invention. However, one having ordinary skill in the art should recognize that the invention may be practiced without these specific details. In some instances, circuits, structures, and techniques have not been shown in detail to avoid obscuring the present invention.

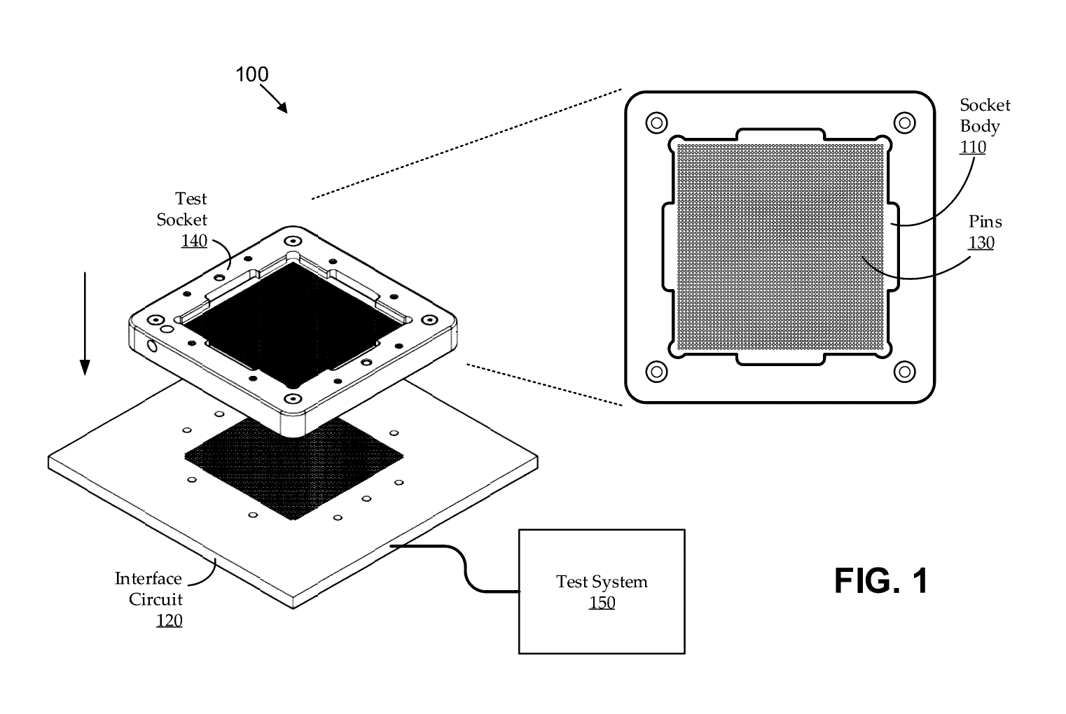

FIG. 1 shows an illustrative integrated circuit (IC) test environment 100 as a context for various embodiments. The test environment 100 includes a test system 150 that can be used to test some or all circuitry of an IC, which can involve electrically coupling some or all of the electrical interconnects of the IC to the test system 150. Often, this can involve designing a custom interface circuit 120, such as a printed circuit board (PCB) that maps (e.g., physically, electrically, logically, etc.) the electrical interconnect layout of the IC to an interface (e.g., connector, port, etc.) of the test system 150. A test socket 140 can also be designed to facilitate interfacing the IC being tested with the custom interface circuit 120. For example, the test socket 140 can provide a physical interface to receive the IC in a manner that facilitates reliable electrical couplings with its interconnects.

It is common for electrical systems, such as ICs to include various types of interconnects. For example, the interconnects can include input/output (I/O) pins, ball grid arrays, and/or other electrical structures implemented on packages for ICs, PCBs, electrical sockets, electrical connectors, electrical interposers, and/or other types of electrical systems. In such structures, the conductors are often arranged in two-dimensional arrays in order to efficiently use the available area. As such, each interconnect is likely adjacent to multiple other interconnects. As described above, testing interconnects of an IC can involve inserting the IC package into the test socket 140 in a manner that electrically couples the various interconnect structures to the test system 150 (e.g., via the custom interface circuit 120).

Interconnects in test sockets 140 are often implemented as spring-loaded conductive pins 130 integrated in a test socket “substrate” or “body” 110. For example, each pin 130 can include a conductive probe disposed in a spring-loaded barrel, and those pins 130 are arranged according to the layout of IC interconnects being tested. For example, inserting an IC into the test socket 140 can create an electrical coupling between each IC interconnect and a respective pin 130, while also causing mechanically compressing the spring-loaded probe inside its barrel to maintaining both good physical and good electrical contact.

As signal speeds continue to increase in many of the ICs being tested, test socket 140 designers have increasingly had to contend with cross-talk, signal return losses, signal integrity issues, etc. One common approach to addressing these issues has been to decrease the length of the contact pin 130 in the test socket 140. Another traditional approach is to manufacture fully-encapsulated coaxial pin structures to insert into the plastic substrate, such pins having center and outer conductors separated by an insulator. The resulting encapsulated, integrated, metal pin manifests as a very short controlled impedance transmission line in a non-conductive contactor body (e.g., many conventional test socket bodies 110 are made of plastic, or other non-conductive materials). In such approaches, the ground return path (in a non-integrated non-specific pin layout) tends to be very poor or nonexistent, and there is often little or no significant performance improvement in signal return losses or cross-talk that would justify the redesign of the test socket 140. Further, as the test socket pins 130 get shorter, it can become increasingly difficult to ensure that all the IC package interconnects maintain reliable mechanical contact with their corresponding test socket 140 interconnects (i.e., to maintain good electrical coupling). For example, particularly in larger test socket 140 structures, it can be difficult or impractical to make the parts flat enough to ensure package-to-socket contact over the entire interconnect array.

Accordingly, embodiments described herein include novel types of full-coaxial signal pins for integration into a test socket 140. The socket body 110 can be made of a conductive metal (e.g., aluminum), and can be drilled with a large number of holes in which the conductive pins 130 can be installed. As described herein, the pins 130 can include ground pins, low-speed signal (LSS) and/or power pins, and coaxial pin assemblies for high-speed signals (HSS). The test socket 140 can include any suitable number and/or arrangement of those and/or other types of pins 130.

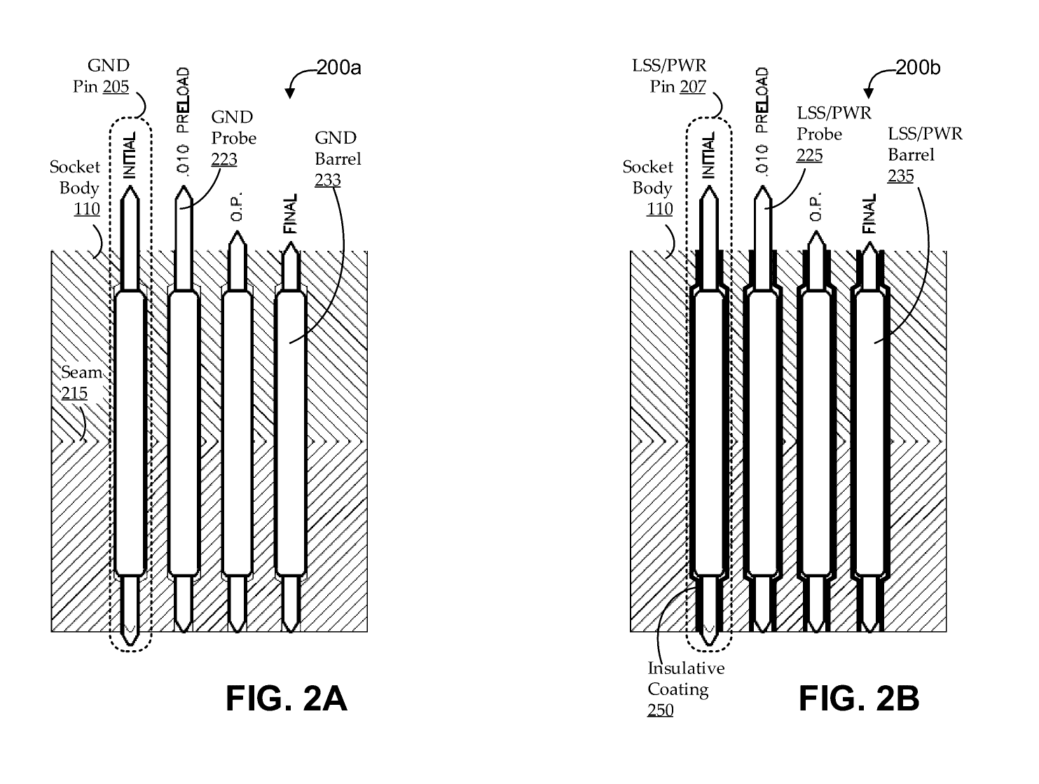

FIGS. 2A and 2B show cross-sectional views 200 of a portion of an illustrative integrated circuit (IC) test socket body 110 having ground pins 205 and power or low-speed signal (LSS) pins 207, respectively, according to various embodiments. In some embodiments, the socket body 110 is made of a conductive metal, such as aluminum. As such, the socket body 110 can act as a ground plane and/or signal return path. In some embodiments, the exposed surfaces of the test socket 140 (e.g., those that contact a test board, IC, etc.) can be insulated (e.g., anodized) to prevent undesired electrical coupling (e.g., shorting, etc.).

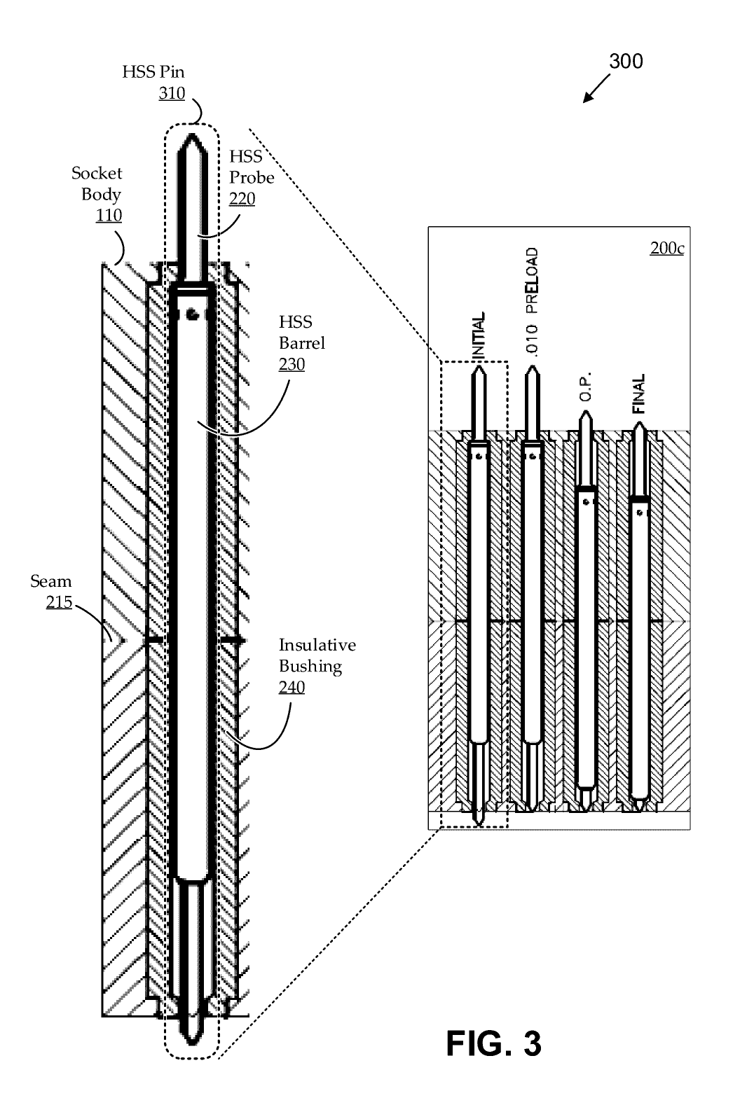

The socket body 110 can be drilled with a number of holes to support interconnects, such as conductive pin assemblies (205 and/or 207), for electrically coupling the IC test socket 140 with an IC (e.g., or any suitable electronic part, not shown). As described below, the holes can be drilled through the IC socket body 110, and can be sized to support different types of interconnects. For example, some implementations described herein have a smallest-diameter hole for ground interconnects, a slightly larger-diameter hole for power interconnects and/or low-speed signal (LSS) interconnects, and a largest-diameter hole for coaxial (e.g., HSS) interconnects (described below with reference to FIG. 3).

The embodiments described herein include interconnects implemented as conductive pin assemblies (205 and/or 207). Each pin assembly includes at least a probe (223 and/or 225) disposed in a spring-loaded barrel (233 and/or 235). The IC test socket 140 can be designed so that interconnects (e.g., pins, ball grid array elements, etc.) of the IC contact corresponding probes (223 and/or 225) of the pin assemblies of the IC test socket 140. Such contact can be designed to compresses the probe (223 and/or 225) inside the barrel (233 and/or 235), and the spring-loaded barrel (233 and/or 235) pushes back against the IC interconnects, thereby maintaining good physical, and thereby electrical, contact.

As illustrated, embodiments of the IC socket body 110 can be manufactured in multiple parts (e.g., as two halves). For example, manufacturing the IC socket body 110 in such a manner can facilitate inserting the pins (205 and/or 207) into their respective holes in a substantially fixed manner (i.e., to substantially secure the pins in their respective holes without using chemical or mechanical fasteners on each pin). Further, while substantially fixed in their respective holes, such an assembly approach can permit the pins (205 and/or 207) to have some float (e.g., vertically) within their respective holes, which can be desirable for improving the operation of the spring-loaded probes (223 and/or 225).

In each of FIGS. 2A and 2B, four pin configurations are illustrated: “INITIAL” illustrates a configuration of the pin (205 and/or 207) when the IC test socket 140 is not coupled with a test board or IC; “PRELOAD” illustrates a configuration of the pin (205 and/or 207) when the IC test socket 140 is coupled with a test board and ready for coupling with an IC; “O.P.” illustrates an operating position configuration of the pin (205 and/or 207) when the IC test socket 140 is normally coupled with a test board and an IC; and “FINAL” illustrates a configuration of the pin (205 and/or 207) when the IC test socket 140 is coupled with a test board and an IC, and the pin (205 and/or 207) is compressed to its limit. The various illustrated configurations are not intended to be limiting, but rather to demonstrate one implementation that provides good mechanical and electrical contact over a range of compression. For example, a large IC may not be perfectly planar, so that there can be a slight variation in where the IC pins contact their corresponding IC test socket 140 pins (205 and/or 207); and the compression range (e.g., between FINAL and PRELOAD, or some sub-range therein) can maintain contact even in context of those variations.

Turning first to FIG. 2A, ground pin 205 configurations are shown. Embodiments of the IC socket body 110 can be drilled to a diameter of a standard spring probe (i.e., a ground pin assembly 205 having a ground probe 223 in a ground barrel 233). The hole can be sized so that the ground pin 105 and makes conductive contact with the socket cavity walls (i.e., most of the outer surface of the ground pin 205 is in conductive contact with the inner surface of the hole). Typically, these ground pin 205 (and corresponding drilled hole) locations correspond to each of the ground pins in an IC being tested by the IC test socket 140, for example according to a CPU package map, or the like. When the IC is connected to the test board via the IC test socket 140, the board and IC test socket 140 can provide a direct ground path for the ground pins of the IC (i.e., through the ground pins 205 of the IC test socket 140).

Turning to FIG. 2B, power and/or LSS pin 207 configurations are shown (i.e., some embodiments can implement power and LSS pins in the same manner). Embodiments of the IC socket body 110 can be drilled to a larger diameter (e.g., slightly larger) than that of a standard spring probe (or slightly larger than that of a ground pin 205). A highly resistive material can then be used to form an insulative coating 250 the inner surface of the hole. For example, a high-resistance anodization layer (e.g., of metallic oxide) can be placed in the drill cavities, and the location can be re-drilled to form a smooth, anodized cavity wall. A power and/or LSS pin 207 can be disposed therein (i.e., a power and/or LSS pin assembly 207 having a power and/or LSS probe 225 in a power and/or LSS barrel 235). In some implementations, the power and/or LSS pin 207 is identical to the ground pin 205 (i.e., the only difference is the presence or absence of the insulative coating 250). The anodizing layer (coating 150) can ensure that the power and/or LSS pin 207 is not in contact with the conductive (e.g., aluminum) IC socket body 110. Typically, each power or LSS pin 207 (and corresponding drilled hole) location corresponds to a respective power pin or LSS pin (e.g., for digital signals of less than 200 MHz) of an IC being tested by the IC test socket 140.

FIG. 3 shows cross-sectional views 300 of a portion of an illustrative integrated circuit (IC) test socket body 110 having coaxial pins 310 for supporting high-speed signals (HSS), respectively, according to various embodiments. For the sake of added clarity, FIG. 3 shows a cross-sectional view 210c similar to those shown in FIGS. 2A and 2B, with a portion of the view enlarged to facilitate identification of certain features. Forming a full-coaxial signal path that is effective for carrying high-speed signals can involve forming an inner conductor and an outer conductor separated by an insulator, and controlling the dimensions, dielectric properties, and/or other characteristics of the conductors and insulators to reliably produce a target impedance.

As described above, the socket body 110 can be drilled with a number of holes to support interconnects, including various types of conductive pin assemblies (205, 207, and/or 310), and the holes can be sized to support different types of interconnects. In some implementations, a larger- (e.g., largest-) diameter hole can be used for the coaxial (or “coax,” “full coax,” HSS, etc.) pins 310 to support the additional insulative bushing 140, as described herein. Some implementations include a hole that is appreciably larger (e.g., double) than that of a standard spring probe. In some implementations, the hole is drilled to an exact diameter that matches a ground return of a targeted high-speed signal impedance.

A full coaxial signal path typically includes an inner conductor surrounded by an insulator, which is further surrounded by an outer conductor. The inner conductor carries the signal, the outer conductor acts as a ground return, and the insulator provides a certain target impedance. In context of coaxial pins 310, it is assumed that the socket body 110 is made of a conductive metal, such as aluminum, thereby acting as the outer conductor (e.g., a ground plane and/or signal return path). As shown, the coaxial pin 103 assembly also includes a coaxial probe 220 and a coaxial barrel 230, which form the inner coaxial conductor. The coaxial insulator is formed by inserting an insulative bushing 240 in the hole between the coaxial pin 310 and the IC socket body 110. In some implementations, the insulative bushing 240 is a plastic bushing made of polytetrafluoroethylene (PTFE). A predetermined target impedance (e.g., determined with respect to a target impedance for the IC being tested, particular signals associated with the pin location, etc.) can be derived from the conductive diameter the spring probe 220 of the coaxial pin 310, and the dielectric constant of the insulating material (i.e., the insulative bushing 240) used in the cavity. The insulative bushing 240 can be formed to provide a controlled spacing between an outer surface of the coaxial pin 310 and an inner surface of the hole in the IC socket body 110. While the coaxial pin 310 is shown as a different type of spring probe than that of the pins in FIGS. 1A and 1B, some implementations can implement all the pins (310, 205, and/or 207) with the same-size (e.g., standard size) spring probe assembly.

Some embodiments are implemented by forming the socket body 110 in multiple parts (e.g., two halves), as indicated by seam 215. For example, pins can be installed (e.g., dropped) into one half of the socket body 110 from the seam side (e.g., the hole is shaped to receive the pin only to a certain depth, such as roughly half the pin length); and the other half of the socket body 110 can be fitted over the installed pins to effectively secure them in their holes. In some implementations, installation of a coaxial pin 310 assembly can include dropping the insulative bushing 240 into an appropriate drilled hole of the socket body 110, and subsequently dropping the coaxial pin 310 (i.e., the probe 220 and barrel 230) into the bushing 240. In other implementations, installation of a coaxial pin 310 assembly can include forming an assembly with coaxial pin 310 (i.e., the probe 220 and barrel 230) and the insulative bushing 240, and dropping the entire assembly into an appropriate drilled hole of the socket body 110. As described above, some implementations include holes drilled that substantially fix the pins in their respective holes, while also permitting the pins to have some float (e.g., vertically) within their respective holes.

As in FIGS. 2A and 2B, FIG. 3 illustrates four pin configurations for an illustrative coaxial pin 310: “INITIAL”; “PRELOAD”; “O.P.”; and “FINAL”. The various illustrated configurations are not intended to be limiting, but rather to demonstrate one implementation that provides good mechanical and electrical contact over a range of compression. For example, such configurations can be used to help ensure good mechanical and electrical contact between the test socket 140 pins (310, 205, and/or 207) and those of an IC under test, even in context of slight variations in the contact plane, interconnect dimensions (e.g., due to manufacturing variance), etc.

Embodiments of the IC test socket 100 described herein can provide a true coaxial signal path that can be properly grounded through the interface PCB board to the device being tested. Conventional designs typically do not provide this type of short, closed ground loop. Embodiments described herein can appreciably improve signal integrity for high-frequency signals, can reduce cross-talk, can provide additional heat sinking (e.g., to draw away heat from the bottom of the device under test), and/or can provide additional features.

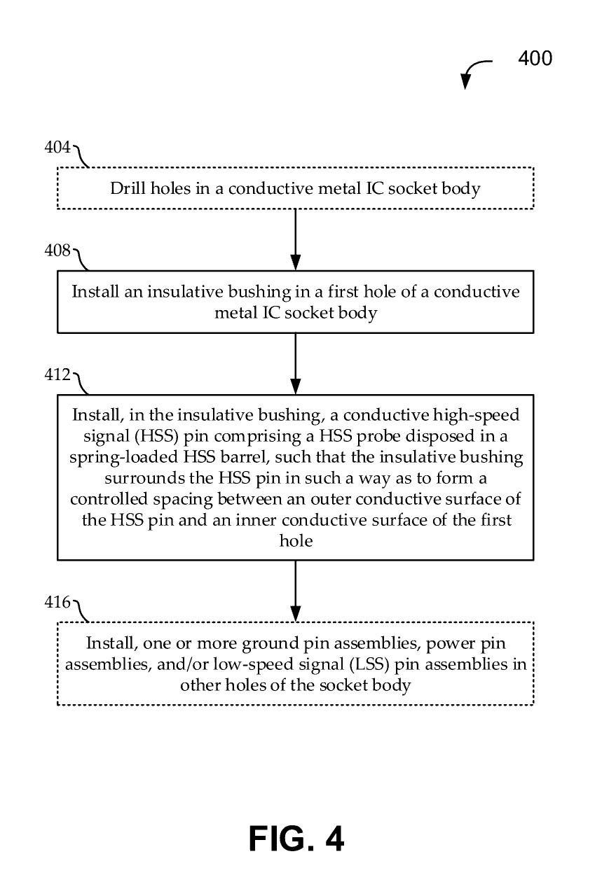

FIG. 4 shows a flow diagram of an illustrative method 400 for providing a coaxial signal path in an integrated circuit (IC) test socket, according to various embodiments. Embodiments of the method 400 begin at stage 408 by installing an insulative bushing in a first hole of a conductive metal IC socket body. At stage 412, embodiments can install, in the insulative bushing, a conductive high-speed signal (HSS) pin having a HSS probe disposed in a spring-loaded HSS barrel. The installation can be performed in such a way that the insulative bushing surrounds the HSS pin to form a controlled spacing between an outer conductive surface of the HSS pin and an inner conductive surface of the first hole. In some implementations, the HSS pin is installed in the insulative bushing at stage 412 prior to the insulative bushing being installed in the first hole at stage 408. In other implementations, the HSS pin is installed in the insulative bushing a stage 412 subsequent to the insulative bushing being installed in the first hole at stage 408.

Some embodiments begin at stage 404 by drilling a number of holes in the conductive metal IC socket body. For example, the holes can be drilled in multiple sizes for different types of pin assemblies. In some implementations, smallest holes are drilled for ground pins, slightly larger holes are drilled for power and/or LSS pins (e.g., to accommodate an insulative coating), and largest-diameter holes are drilled for coaxial pins (e.g., to accommodate the insulative bushing).

In some embodiments, at stage 416 (which can occur before, after, or concurrently with stages 408 and 412), one or more ground pins, power pins, and/or LSS pins can be installed in the other holes of the conductive metal IC socket body. For example, embodiments can include installing, in a second hole of the conductive metal IC socket body, a ground pin assembly comprising a conductive ground pin having a ground probe disposed in a spring-loaded ground barrel, the installing forming substantial electrical contact between an outer surface of the ground pin and an inner surface of the second hole. Other embodiments can include coating an inner surface of a second hole of the conductive metal IC socket body with an insulative coating, and installing, in the second hole, a low-speed signal (LSS) pin assembly (e.g., which can be used as a power pin assembly) comprising a conductive LSS pin having a LSS probe disposed in a spring-loaded LSS barrel; so that the insulative coating surrounds the LSS pin in such a way as to electrically insulate an outer surface of the power pin from the inner surface of the second hole.

Various changes, substitutions, and alterations to the techniques described herein can be made without departing from the technology of the teachings as defined by the appended claims. Moreover, the scope of the disclosure and claims is not limited to the particular aspects of the process, machine, manufacture, composition of matter, means, methods, and actions described above. Processes, machines, manufacture, compositions of matter, means, methods, or actions, presently existing or later to be developed, that perform substantially the same function or achieve substantially the same result as the corresponding aspects described herein may be utilized. Accordingly, the appended claims include within their scope such processes, machines, manufacture, compositions of matter, means, methods, or actions.

What is claimed is:

1. An integrated circuit (IC) test socket comprising:
a conductive metal IC socket body comprising a plurality of holes; and
a coaxial pin assembly installed in a first of the holes and comprising:
a conductive high-speed signal (HSS) pin comprising a HSS probe disposed in a spring-loaded HSS barrel; and
an insulative bushing disposed in the first hole and surrounding the HSS pin in such a way as to form a controlled spacing between an outer surface of the HSS pin and an inner surface of the first hole.

2. The IC test socket of claim 1, wherein:
each hole has a height defined according to a thickness of the IC socket body through which the hole is drilled; and
the insulative bushing extends over substantially the height of the first hole.

3. The IC test socket of claim 1, further comprising:
a ground pin assembly comprising a conductive ground pin having a ground probe disposed in a spring-loaded ground barrel,
wherein the ground pin assembly is installed in a second of the holes in such a way as to form substantial electrical contact between an outer surface of the ground pin and an inner surface of the second hole.

4. The IC test socket of claim 1, further comprising:
a power pin assembly installed in a second of the holes and comprising:
a conductive power pin having a power probe disposed in a spring-loaded power barrel; and
an insulative coating disposed on an inner surface of the second hole surrounding the power pin in such a way as to electrically insulate an outer surface of the power pin from the inner surface of the second hole.

5. The IC test socket of claim 1, further comprising:
a low-speed signal (LSS) pin assembly installed in a second of the holes and comprising:
a conductive LSS pin having a LSS probe disposed in a spring-loaded LSS barrel; and
an insulative coating disposed on an inner surface of the second hole surrounding the LSS pin in such a way as to electrically insulate an outer surface of the LSS pin from the inner surface of the second hole.

6. The IC test socket of claim 1, wherein the coaxial pin assembly is one of a plurality of coaxial pin assemblies installed in a first plurality of the holes, and further comprising:
a plurality of ground pin assemblies installed in a second plurality of the holes, each comprising a conductive ground pin having a ground probe disposed in a spring-loaded ground barrel; and
a plurality of low-speed signal (LSS) pin assemblies installed in a third plurality of the holes, each comprising a conductive LSS pin having a LSS probe disposed in a spring-loaded LSS barrel, and an insulative coating disposed on an inner surface of the second hole surrounding the LSS pin in such a way as to electrically insulate an outer surface of the LSS pin from the inner surface of the second hole.

7. The IC test socket of claim 6, wherein:
each of the first plurality of the holes is drilled to a first diameter;
each of the second plurality of the holes is drilled to a second diameter that is smaller than the first diameter; and
each of the third plurality of the holes is drilled to a third diameter that is smaller than the first diameter and larger than the second diameter.

8. The IC test socket of claim 1, wherein:
the first hole is drilled to a diameter that matches a ground return of a pre-targeted high-speed signal impedance.

9. The IC test socket of claim 1, wherein:
the HSS pin defines a conductive diameter;
the insulative bushing defines a dielectric constant; and
dimensions of the HSS pin and the insulative bushing are determined to yield a predefined target impedance as a function of the conductive diameter and the dielectric constant.

10. The IC test socket of claim 1, wherein the IC socket body is made of aluminum.

11. The IC test socket of claim 1, wherein the insulative bushing is made of polytetrafluoroethylene (PTFE).

12. A coaxial pin assembly comprising:
a conductive high-speed signal (HSS) pin comprising a HSS probe disposed in a spring-loaded HSS barrel; and
an insulative bushing disposed in the first hole and surrounding the HSS pin in such a way as to form a controlled spacing between an outer surface of the HSS pin and an inner surface of the first hole.

13. The coaxial pin assembly of claim 12, wherein the insulative bushing is made of polytetrafluoroethylene (PTFE).

14. A method for providing a coaxial signal path in an integrated circuit (IC) test socket, the method comprising:
installing an insulative bushing in a first hole of a conductive metal IC socket body; and
installing, in the insulative bushing, a conductive high-speed signal (HSS) pin comprising a HSS probe disposed in a spring-loaded HSS barrel,
such that the insulative bushing surrounds the HSS pin in such a way as to form a controlled spacing between an outer conductive surface of the HSS pin and an inner conductive surface of the first hole.

15. The method of claim 14, wherein the HSS pin is installed in the insulative bushing prior to the insulative bushing being installed in the first hole.

16. The method of claim 14, wherein the HSS pin is installed in the insulative bushing subsequent to the insulative bushing being installed in the first hole.

17. The method of claim 14, further comprising:
installing, in a second hole of the conductive metal IC socket body, a ground pin assembly comprising a conductive ground pin having a ground probe disposed in a spring-loaded ground barrel, the installing forming substantial electrical contact between an outer surface of the ground pin and an inner surface of the second hole.

18. The method of claim 17, further comprising:
drilling a first plurality of holes in the conductive metal IC socket body prior to installing the insulative bushing, the first plurality of holes being drilled to a first diameter, the first hole being one of the first plurality of holes; and
drilling a second plurality of holes in the conductive metal IC socket body prior to installing the ground pin assembly, the second plurality of holes being drilled to a second diameter that is smaller than the first diameter, the second hole being one of the second plurality of holes.

19. The method of claim 14, further comprising:
coating an inner surface of a second hole of the conductive metal IC socket body with an insulative coating; and
installing, in the second hole, a low-speed signal (LSS) pin assembly comprising a conductive LSS pin having a LSS probe disposed in a spring-loaded LSS barrel,
wherein the insulative coating surrounds the LSS pin in such a way as to electrically insulate an outer surface of the power pin from the inner surface of the second hole.

20. The method of claim 19, wherein the LSS pin assembly is a power pin assembly.
